(19) United States
(12) Patent Application Publication
(10) Pub. No.: US 2005/0275075 A1
(43) Pub. Date: Dec. 15, 2005

(54) Micro-electro-mechanical system (MEMS) package with spacer for sealing and method of manufacturing the same

(76) Inventors: Suk-Kee Hong, Seoul (KR); Chang-Su Park, Kyunggi-do (KR); Ohk-Kun Lim, Kyunggi-do (KR)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(21) Appl. No.: 10/952,248

(22) Filed: Sep. 28, 2004

(30) Foreign Application Priority Data
Jun. 11, 2004 (KR) 2004-43026

(51) Int. Cl. H01L 23/02; H01L 21/48

(52) U.S. Cl. 257/678; 257/704; 438/121; 438/125

(57) ABSTRACT

A micro-electro-mechanical system (MEMS) package with a spacer for sealing and a method of manufacturing the package are disclosed. The MEMS package and method of the present invention hermetically and reliably seals MEMS elements from an external environment, including temperature, humidity, impact and vibration, by a sealing unit which has a spacer integrated with a lid glass to secure an MEMS moving space where the MEMS elements are free to move vertically. The present invention simplifies the process of manufacturing the MEMS package and prevents solder from flowing into the package. The MEMS package and method according to the present invention also allow a reworking process, such as for adding solder, to be executed when the sealing is not complete due to inaccurate positioning of the solder and/or application of a deficient amount of solder to a junction between the base substrate and the lid glass.

### BACKGROUND OF THE INVENTION

1. Field of the Invention

The present invention relates, in general, to micro-electro-mechanical system (MEMS) packages with sealing spacers and methods of manufacturing the packages and, more particularly, to an MEMS package and a method of manufacturing the package, in which MEMS elements are hermetically sealed from the external environment by a sealing unit having a spacer which is integrated with a lid glass and secures an MEMS moving space where the MEMS elements are free to move vertically.

2. Description of the Related Art

In recent years, high-capacity communications for broadband service, such as in the Internet or the IMT 2000, have become powerful, so that optical communication technique including, for example, WDM (wavelength division multiplexing), has been quickly standardized. In relation to the standardization of the optical communication technique, MEMS, which does not depend on wavelength, data rate or signal format and thereby has characteristics of being “optically transparent”, has been proposed and recognized as an innovative technique to supplant electronics, which can accomplish the recent trend of system smallness.

In the related art, current applications of MEMS are accelerometers, pressure sensors, inkjet heads, hard disk heads, projection displays, scanners and micro-fluidics. In recent years, interest in the technique of optical communication elements with higher operational performances to meet the rapid development in the optical communications field has increased.

Particularly, the interest in the technique of the optical communication elements is concentrated to spatial light modulators, which have a great number of micromirrors and operate in a specified switching manner that the micromirrors are actuated by MEMS type actuators. The spatial light modulators use an optical signal processing technique with advantages in that a great amount of data can be quickly processed in a parallel manner, unlike a conventional digital information processing technique, in which a great amount of data cannot be processed in real time.

Thus, studies have been actively conducted on the design and production of binary phase only filters, optical logic gates, light amplifiers, image processing techniques, optical devices, and light modulators using the spatial light modulation theory. Of them, the spatial light modulators are applied to optical memories, optical display devices, printers, optical interconnections, and hologram fields, and studies have been conducted to develop display devices employing the spatial display modulators.

However, the MEMS elements have ultra-fine actuators so that the MEMS elements are greatly sensitive to the external environment, including temperature, humidity, micro-dust, vibration and impact, and thereby may frequently commit errors during operation or suddenly stop operation.

In an effort to allow the MEMS elements to effectively operate without being negatively affected by the environment, the MEMS elements have been sealed in cavities of sealed packages. U.S. Pat. No. 6,303,986 discloses a method and apparatus for sealing MEMS elements using a hermetic lid to provide an MEMS package.

Herein below, the construction of the MEMS package disclosed in U.S. Pat. No. 6,303,986, in which the lid glass hermetically seals the MEMS elements from the external environment, will be described with reference to FIG. 1.

FIG. 1 shows a representative sectional view of the MEMS package in which the transparent lid hermetically seals the MEMS element. As shown in FIG. 1, a conductive ribbon 100 having a metallic conductive/reflective covering 102 is formed over an upper surface of a semiconductor substrate 104, with an air gap 106 defined between the ribbon 100 and the substrate 104.

A conductive electrode 108 is formed on the upper surface of the substrate 104 and covered with an insulation layer 110. The conductive electrode 108 is placed under the ribbon 100 at a position under the air gap 106.

The conductive/reflective covering 102 extends beyond the region of the mechanically active ribbon 100 and is configured as a bond pad 112 at its distal end. The MEMS package is also passivated with a conventional overlying insulating passivation layer 114 which does not cover the bond pads 112 or the ribbon structures 100 and 102.

Control and power signals are coupled to the MEMS package using conventional wire-bonding structures 116.

Unlike conventional semiconductor manufacturing techniques in which semiconductor elements are packed densely onto the upper surface of a semiconductor substrate, an optical glass is hermetically sealed directly onto the semiconductor substrate in the above-mentioned US patent. Thus, the bond pads 112 are spaced a considerable distance from the ribbon structures 100 and 102, so that a lid sealing region 118 is provided. A solderable material 120 is formed onto the lid sealing region 118.

The hermetic lid 122, which is joined to the semiconductor substrate, is preferably formed of an optical quality material. Thus, the lid 122 can be used for a variety of purposes including filtering undesired radiation, enhancing reflectivity, or decreasing reflectivity.

The lid 122 may be also coated with an optically sensitive material to be used for other purposes without being limited to the above-mentioned purposes.

Once the lid 122 is formed to a size appropriate to fit concurrently over the lid sealing region 118, with a solderable material 124 formed in a ring surrounding the periphery of one surface of the lid 122, solder 126 is deposited onto the solderable material 124 so that the lid 122 is joined to the semiconductor substrate.

Though not shown to scale in the drawing, a significant space exists between the lid 122 and the ribbon structures 100 and 102 to prevent them from interfering with one another. Thus, the ribbon structures 100 and 102 are free to move upwards and downwards.

FIG. 2 shows a plan view of an exemplary package disclosed in the above-mentioned US patent wherein various regions are shown as blocks. As shown in the drawing, the ribbon structures of a GLV (diffraction grating light valve) to be used as a display engine comprise a mechanically active region 140, while the lid sealing region 118 surrounds the mechanically active region 140.

In this case, the lid sealing region 118 is passivated and includes no mechanically active elements, such as those traditionally found in MEMS devices.

Furthermore, the lid sealing region 118 includes no bond pads where other off-chip interface structures, such as the lid 122, would interfere with the effective operation of the MEMS device. However, it is possible that the lid sealing region 118 could include active electronic elements. In the event that the lid sealing region 118 did include active electronic elements, effort must be taken to planarize that region in order to provide the surface to which the lid 122 can properly mate.

The bonding region 142 surrounds the lid sealing region 118, and includes several bond pads 114 necessary for making interconnection from the package to off-chip circuits and systems.

Herein below, the method of sealing a hermetic lid to a semiconductor substrate to provide an MEMS package will be described in detail with reference to FIGS. 3a and 3b.

As shown in FIG. 3a, a first solderable material 150 is formed onto the lid sealing region 152 of the semiconductor substrate 154. A second solderable material 156 is also formed around the peripheral edges of the transparent lid 158. Thereafter, a layer of solder 160 is formed over the layer of second solderable material 156.

The transparent lid 158 is brought into contact with and aligned to the semiconductor substrate 154 to provide an assembly. Heat is applied to the assembly, thus allowing the solder 160 to be melted.

In that case, surface tension of the melted solder 160′ causes the solder 160′ to remain between the first solderable material 150 on the semiconductor substrate 154 and the second solderable material 156 on the transparent lid 158.

Thereafter, the assembly is heated for a sufficient time to allow the solder 160′ to flow and wet all solderable surfaces. Once the heat is removed, the solder 160′ is re-solidified, and the transparent lid 158 is hermetically sealed to the semiconductor substrate 154 as shown in FIG. 3b.

However, in the above-mentioned method of sealing the semiconductor elements in the MEMS package, the solder must be placed between the substrate and the lid and, thereafter, heat must be applied to the solder through a reflow process at a predetermined temperature so as to bond the lid to the substrate. Thus, the method undesirably reduces the work speed to cause a reduction in productivity.

Another problem of the above-mentioned method is that it is impossible to execute a reworking process, such as for adding solder, even when the sealing is not complete due to inaccurate positioning of the solder and/or application of a deficient amount of solder to the junction between the substrate and the lid.

### SUMMARY OF THE INVENTION

Accordingly, the present invention has been made keeping in mind the above problems occurring in the related art, and an object of the present invention is to provide an MEMS package and a method of manufacturing the package, in which MEMS elements are hermetically sealed from the external environment by a sealing unit having a spacer which is integrated with a lid glass and secures an MEMS moving space where the MEMS elements are free to move vertically.

In order to achieve the above object, according to one aspect of the present invention, there is provided a micro-electro-mechanical system (MEMS) package with a spacer for sealing, comprising: a base substrate provided with an MEMS element thereon; a first joining unit provided on the base substrate while surrounding the MEMS element; and a sealing unit mounted by means of the first joining unit to the base substrate having the MEMS element so that the sealing unit hermetically seals the MEMS element from an external environment, the sealing unit comprising: a lid glass to cover a predetermined region of the base substrate on which the MEMS element is provided; a second joining unit provided on a predetermined region of the lid glass; and a spacer mounted to the lid glass by means of the second joining unit, thus being integrated with the lid glass and securing an MEMS moving space where the MEMS element is free to move vertically.

According to another aspect of the present invention, there is provided a method of manufacturing a micro-electro-mechanical system (MEMS) package with a spacer for sealing, comprising: providing an MEMS element on a base substrate; providing a first joining unit on the base substrate so that the first joining unit surrounds the MEMS element; preparing a sealing unit which hermetically seals the MEMS element of the base substrate from an external environment; and mounting the sealing unit to the base substrate using the first joining unit, thus hermetically sealing the MEMS element from the external environment.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a sectional view illustrating the construction of a conventional MEMS package;

FIG. 2 is a plan view of an embodiment of the package of FIG. 1;

FIGS. 3a and 3b are views illustrating a process of sealing a hermetic lid to a semiconductor substrate to provide the package of FIG. 1;

FIGS. 4 through 8 are sectional views of MEMS packages according to embodiments of the present invention; and

FIGS. 9a through 9q are views illustrating a process of manufacturing an MEMS package with a sealing spacer according to the present invention.

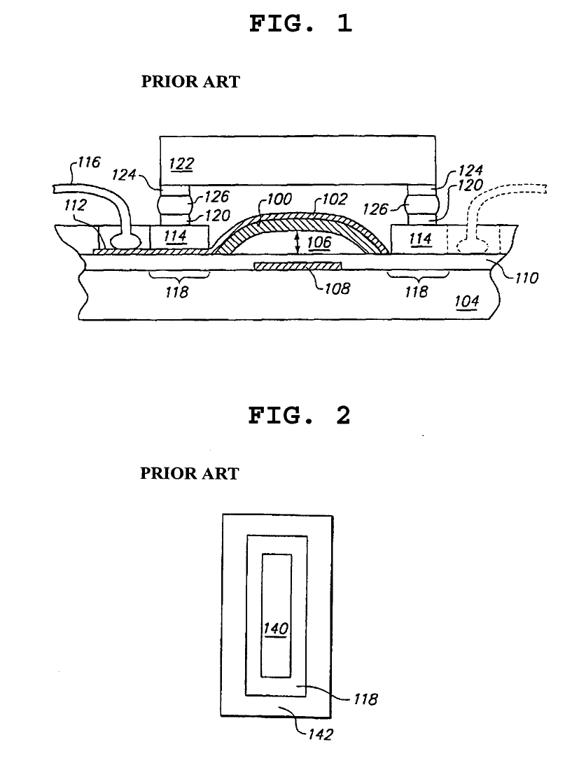

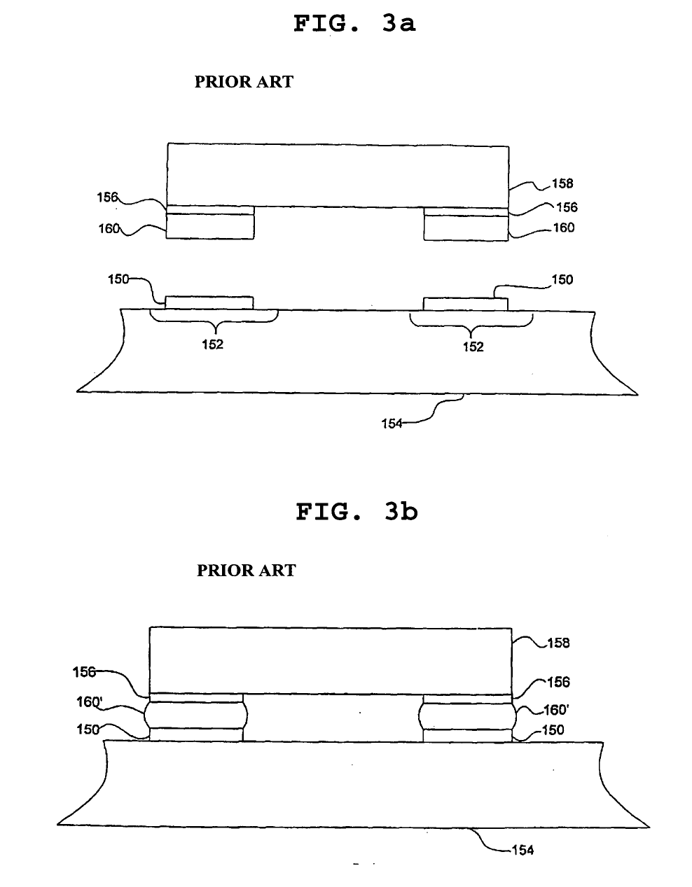

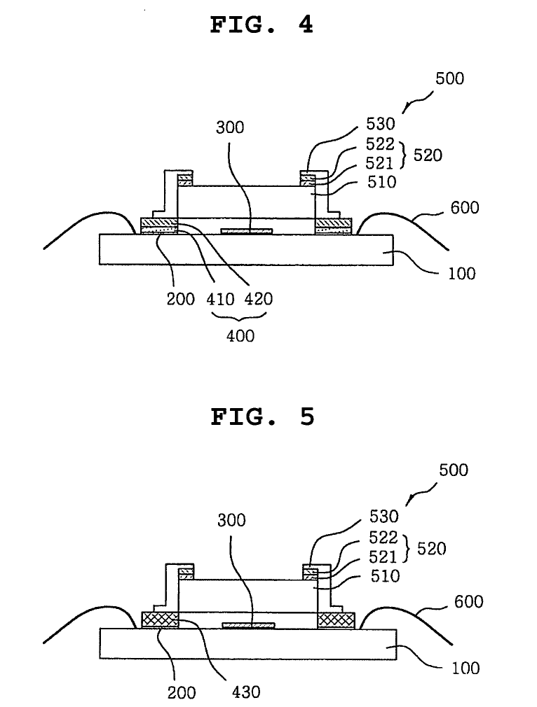

### DETAILED DESCRIPTION OF THE INVENTION

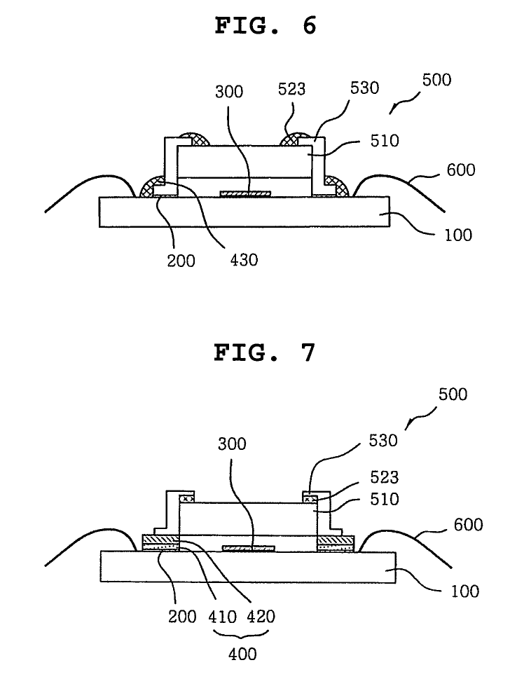

Herein below, an MEMS package with a spacer for sealing and a method of manufacturing the MEMS package according to the present invention will be described in detail with reference to the accompanying drawings, FIGS. 4 through 9q.

First, the construction of MEMS packages with sealing spacers according to embodiments of the present invention will be described in detail in conjunction with FIGS. 4 through 8.

In each of the MEMS packages shown in FIGS. 4 through 8, MEMS elements are provided on a base substrate.

In the present invention, each of the MEMS packages is configured such that MEMS elements provided on a base substrate are hermetically sealed from the external environment by a sealing unit which is formed by integrating a spacer with a lid glass to cover the MEMS elements. As shown in FIGS. 4 through 8, the MEMS package according to the present invention comprises a base substrate 100 on which MEMS elements 300 are provided, an insulating passivation layer 200, a first joining unit 400 and a sealing unit 500.

The base substrate 100 may be a semiconductor substrate on which the MEMS elements 300 are formed, or a conventional PCB (printed circuit board) on which the MEMS elements 300 are bonded through die-bonding so that the PCB serves as an element carrier. The base substrate 100 is provided with bond pads (not shown) to which wires 600 are connected so as to transceive electric signals with an external circuit.

In that case, examples of the MEMS elements 300 are diffractive, reflective or transmissive light modulating elements, optical elements or display elements used in a variety of optical devices, such as optical memories, optical displays, printers, optical interconnections, and hologram displays.

The insulating passivation layer 200, which is formed on the upper surface of the base substrate 100, is a protective layer made of an insulating material, such as SiO₂ or SiNₓ. Thus, the insulating passivation layer 200 protects the base substrate 100 from damage during continued processes and functions to prevent the MEMS elements 300 from being short-circuited to the base substrate 100.

The first joining unit 400 serves as a means for joining the sealing unit 500, which hermetically seals the MEMS elements 300 on the base substrate 100 from the external environment, to the base substrate 100. In the embodiment of FIG. 4, the first joining unit 400 comprises a solderable metal layer 410 and a solder 420.

The solderable metal layer 410 is formed on the passivation layer 200 of the base substrate 100 by patterning a conductive metal through a sputtering or metalorganic chemical vapor deposition (MOCVD) process so that the metal layer 410 surrounds the MEMS elements 300.

In that case, the solderable metal layer 410 serves as a joining layer through which the solder 420 is easily united to the base substrate 100.

The solder 420 is formed on the solderable metal layer 410 through a soldering process, and joins the sealing unit 500, which hermetically seals the MEMS elements 300 on the base substrate 100 from the external environment, to the base substrate 100.

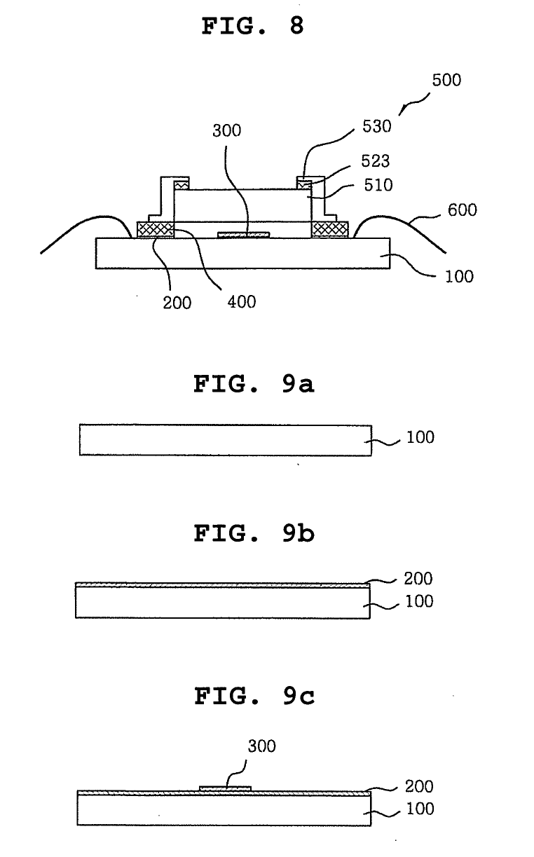

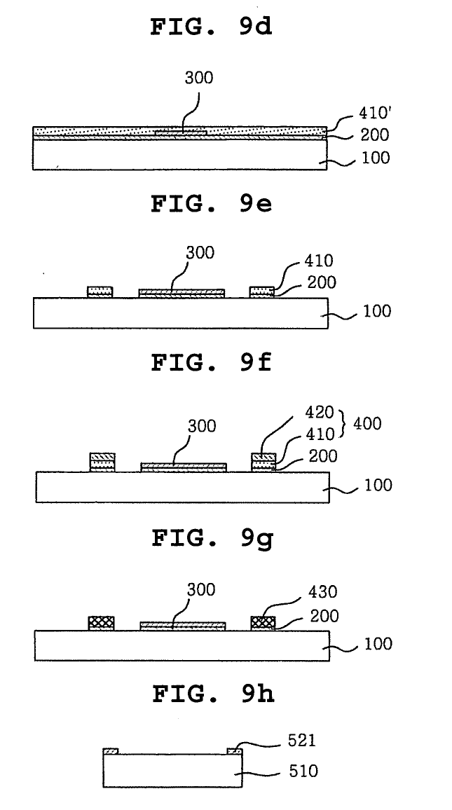

In other embodiments of the present invention, the first joining unit 400, which serves as the means for joining the sealing unit 500 to the base substrate 100, is formed of an epoxy resin 430 in place of the metal layer 410 and the solder 420 as shown in FIGS. 5 and 6.

In that case, the epoxy resin 430 may be applied between the base substrate 100 and the sealing unit 500 as shown in FIG. 5. Alternatively, the epoxy resin 430 may be applied to the outside surface of the sealing unit 500 as shown in FIG. 6.

The sealing unit 500 is joined to the upper surface of the base substrate 100 by means of the first joining unit 400, thus sealing the MEMS elements 300 from the external environment. The sealing unit 500 comprises a lid glass 510, a second joining unit 520 and a spacer 530 which is integrated with the lid glass 510 as shown in FIGS. 4 and 5.

The lid glass 510 covers the MEMS elements 300 on the base substrate 100 so as to protect the MEMS elements 300 from the external environment, including temperature, humidity, micro-dust, vibration and impact.

In the present invention, the lid glass 510 may be coated on one or both sides thereof with an antireflective (AR) coating so that incident light transmissibility of the lid glass 510 can be enhanced.

The second joining unit 520 is provided on the lid glass 510 to join the spacer 530 to the lid glass 510. In other words, the spacer 530 is integrated with the lid glass 510 by means of the second joining unit 520. Due to the spacer 530, an MEMS moving space where the MEMS elements 300 are free to move vertically is secured above a predetermined region of the base substrate 100.

The second joining unit 520, which joins the spacer 530 to a predetermined region of the lid glass 510 so as to integrate the spacer 530 and the lid glass 510 into a single structure, may comprise a solderable metal layer 521 and solder 522 as shown in FIGS. 4 and 5.

The solderable metal layer 521 is formed of a metal through a metallization process so that the solder 522 that integrates the spacer 530 with the lid glass 510 is firmly joined to a predetermined region of the lid glass 510 by the metal layer 521.

In a detailed description, as the lid glass 510 comprises a glass component, the joining material, such as the solder 522, may fail to reliably maintain its firmly attached state on the lid glass 510, but may be suddenly, separated from the lid glass 510. Thus, in order to prevent the separation of the joining material from the lid glass 510, the solderable metal layer 521 is formed on a predetermined region of the lid glass 510 through a metallization process with a conductive metal, for example, gold, nickel, or a gold/nickel alloy.

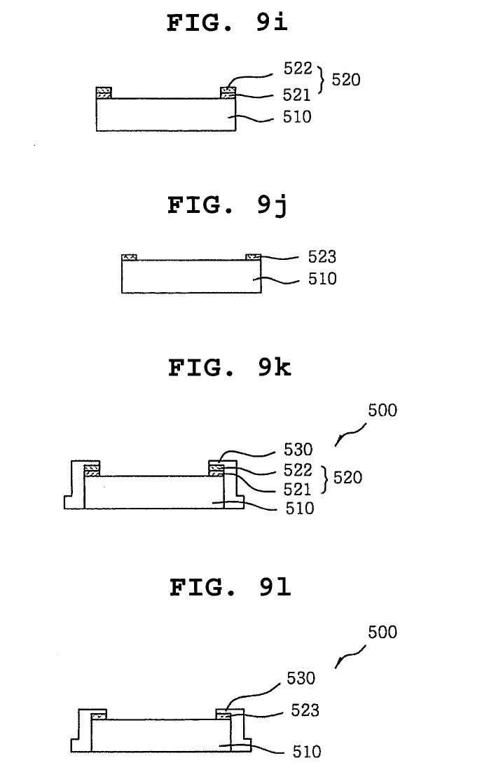

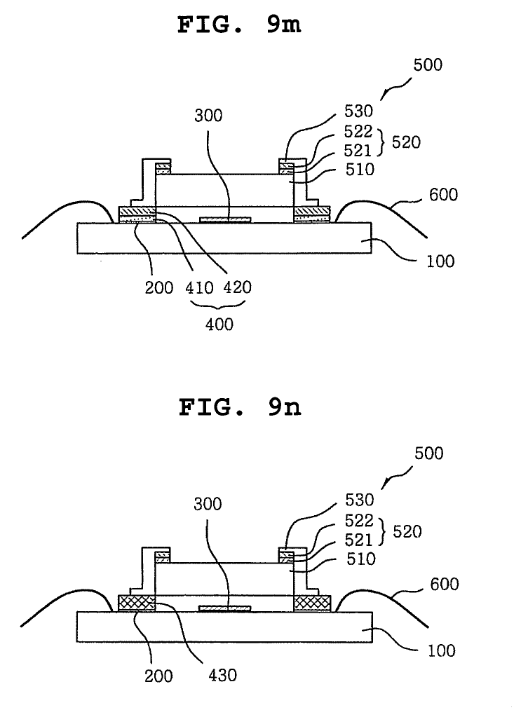

The second joining unit 520, which joins the spacer 530 to the predetermined region of the lid glass 510 so as to integrate the spacer 530 and the lid glass 510 into a single structure, may be formed of an epoxy resin 523 in place of the metal layer 521 and the solder 52 as shown in FIGS. 7 and 8.

In that case, the epoxy resin 523 used as the second joining unit 520 may be applied between the lid glass 510 and the spacer 530 as shown in FIGS. 7 and 8, or may be applied to a side surface of the spacer 530 as shown in FIG. 6.

The spacer 530 is joined to the predetermined region of the lid glass 510 using the second joining unit 520 as described above, and secures an MEMS moving space where the MEMS elements 300 provided on the base substrate 100 are free to move vertically. In the present invention, the spacer 530 is made of metal or glass.

After the sealing unit 500 is hermetically mounted to the base substrate 100 using the first joining unit 400 as described above, wires 600 are connected to the bond pads (not shown) provided on the base substrate 100 at predetermined positions. Thus, an MEMS package of the present invention, in which the MEMS elements 300 provided on the base substrate 100 are hermetically sealed from the external environment, is produced.

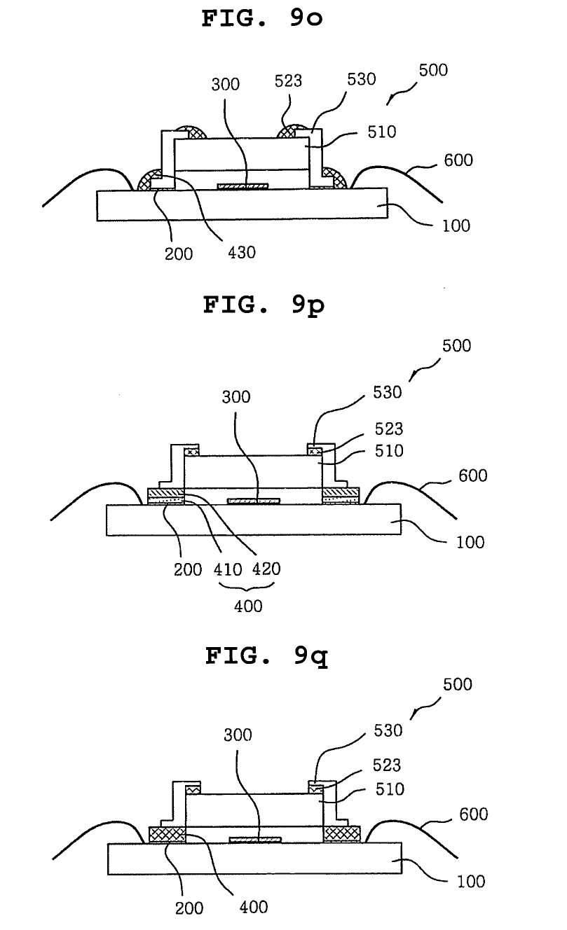

Herein below, the method of manufacturing the MEMS package with a sealing spacer according to the present invention will be described with reference to FIGS. 9a through 9q.

First, an insulating passivation layer 200 is formed on the upper surface of a base substrate 100 as shown in FIGS. 9a and 9b before MEMS elements 300 are provided on the base substrate 100.

In that case, the base substrate 100 may be a semiconductor substrate on which the MEMS elements 300 are formed, or a conventional PCB on which the MEMS elements 300 are bonded through die-bonding so that the PCB serves as an element carrier.

Furthermore, the insulating passivation layer 200, which is formed on the upper surface of the base substrate 100, is a protective layer made of an insulating material, such as SiO₂ or SiNₓ, so that the insulating passivation layer 200 protects the base substrate 100 from damage during continued processes and functions to prevent the MEMS elements 300 from being short-circuited to the base substrate 100.

After the insulating passivation layer 200 is formed on the upper surface of the base substrate 100 as described above, the MEMS elements 300 are provided on the base substrate 100 with the passivation layer 200 interposed between the base substrate 100 and the MEMS elements 300 as shown in FIG. 9c.

In that case, the MEMS elements 300 may be diffractive, reflective or transmissive light modulating elements, optical elements or display elements used in a variety of optical devices, such as optical memories, optical displays, printers, optical interconnections, and hologram displays.

The MEMS elements 300 may be formed on the base substrate 100 so that the elements 300 are integrated with the substrate 100. Alternatively, the MEMS elements 300 may be produced separately from the base substrate 100 prior to being mounted to the upper surface of the base substrate 100.

After the MEMS elements 300 are provided on the base substrate 100 with the insulating passivation layer 200 interposed between the substrate 100 and the elements 300 as described above, a first joining unit 400 having a predetermined construction and shape to mount a sealing unit 500 to the base substrate 100 is formed on the substrate 100.

In that case, the first joining unit 400 is formed to surround the MEMS elements 300 on the base substrate 100 while being spaced apart from the elements 300, and serves as a joining layer through which the sealing unit 500 is easily united to the base substrate 100.

In a detailed description, to provide the first joining unit 400, a conductive metal 410′, such as gold, nickel, or a gold/nickel alloy, is deposited on the base substrate 100 having the MEMS elements 300 thereon as shown in FIG. 9d.

Thereafter, a masking process for the conductive metal 410′ is executed to remove the conductive metal 410′ while leaving only a part of the conductive metal 410′ formed on a specified region designated for solder 420. Thus, a solderable metal layer 410 having a predetermined shape is provided on the base substrate 100 as shown in FIG. 9e.

Thereafter, the solder 420, which serves as a joining material for joining the sealing unit 500 to the base substrate 100, is formed on the solderable metal layer 410 so that the first joining unit 400 is completely formed on the base substrate 100 as shown in FIG. 9f.

In the present invention, the first joining unit 400, which serves as a means for joining the MEMS element sealing unit 500 to the base substrate 100, may be formed of an epoxy resin 430 in place of the metal layer 410 and the solder 420 as shown in FIG. 9g.

After the first joining unit 400 is formed on the base substrate 100 as described above, a sealing unit 500 is mounted to the substrate 100 so as to hermetically seal the MEMS elements 300 from the external environment.

To hermetically seal the MEMS elements 300 on the base substrate 100 from the external environment using the sealing unit 500, the sealing unit 500 must be prepared.

To prepare the sealing unit 500, a metallization process is executed on a predetermined region of a lid glass 510 which is used for covering the MEMS elements 300 on the base substrate 100. Thus, a solderable metal layer 521 is formed on the lid glass 510 as shown in FIG. 9h. On the solderable metal layer 521, solder will be formed during a continued process as follows.

Thereafter, a soldering process is executed on the solderable metal layer 521, thus forming solder 522 on the metal layer 521. Therefore, a second joining unit 520 is completely formed on a predetermined portion of the lid glass 510 as shown in FIG. 9i. Due to the solder 522, a spacer 530 for securing an MEMS moving space where the MEMS elements 300 are free to move vertically can be mounted to the lid glass 510.

In the present invention, the second joining unit 520, which joins the spacer 530 to the predetermined region of the lid glass 510 so as to integrate the spacer 530 and the lid glass 510 into a single structure, may be formed of an epoxy resin 523 in place of the metal layer 521 and the solder 522 as shown in FIG. 9j.

After the second joining unit 520 is formed, the spacer 530, which secures the MEMS moving space where the MEMS elements 300 freely move vertically, is mounted to the lid glass 510 using the second joining unit 520. Thus, the sealing unit 500, which hermetically seals the MEMS elements 300 of the base substrate 100 from the external environment, is completely prepared as shown in FIGS. 9k and 9l.

At this time, the spacer 530 is made of metal, epoxy resin, plastic or glass and has a height to sufficiently provide the MEMS moving space where the MEMS elements 300 of the base substrate 100 freely move vertically.

After the sealing unit 500 is completely prepared, the sealing unit 500 is mounted using the second joining unit 400 to the predetermined region of the base substrate 100 having the MEMS elements 300. Thus, the MEMS elements 300 are hermetically sealed from the external environment, including temperature, humidity, micro-dust, vibration and impact.

After the MEMS elements 300 of the base substrate 100 are hermetically sealed from the external environment by the sealing unit 500, wires 600 are connected through wire-bonding to bond pads (not shown) provided on predetermined positions of the base substrate 100 which are electrically coupled to the MEMS elements 300. Thus, an MEMS package of the present invention, in which signals from the MEMS elements 300 are transmitted to an external circuit through the wires 600, is produced as shown in FIGS. 9m through 9q.

As is apparent from the above description, the MEMS package and method of manufacturing the package according to the present invention hermetically and reliably seals MEMS elements from the external environment, including temperature, humidity, impact and vibration, by a sealing unit comprising a spacer which is integrated with an MEMS element covering lid glass to secure an MEMS moving space where the MEMS elements are free to move vertically.

Furthermore, as the MEMS package and method of manufacturing the package according to the present invention hermetically seal the MEMS elements from the external environment by a sealing unit comprising a spacer integrated with a lid glass, the present invention simplifies the process of manufacturing the MEMS package and prevents solder from flowing into the package unlike conventional MEMS packages and conventional manufacturing methods. The MEMS package and method according to the present invention also allow a reworking process, such as for adding solder, to be executed when the sealing is not complete due to inaccurate positioning of the solder and/or application of a deficient amount of solder to a junction between the base substrate and the lid glass.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A micro-electro-mechanical system (MEMS) package with a spacer for sealing, comprising:
a base substrate provided with an MEMS element thereon;
a first joining unit provided on the base substrate while surrounding the MEMS element; and
a sealing unit mounted by means of the first joining unit to the base substrate having the MEMS element so that the sealing unit hermetically seals the MEMS element from an external environment, the sealing unit comprising:
a lid glass to cover a predetermined region of the base substrate on which the MEMS element is provided;
a second joining unit provided on a predetermined region of the lid glass; and
a spacer mounted to the lid glass by means of the second joining unit, thus being integrated with the lid glass and securing an MEMS moving space where the MEMS element is free to move vertically.

2. The MEMS package as set forth in claim 1, further comprising:
a passivation layer provided between the base substrate and the first joining unit so as to protect the base substrate from damage and prevent the MEMS element from being short-circuited to the base substrate.

3. The MEMS package as set forth in claim 1, wherein the first joining unit comprises:
a metal layer having a predetermined shape formed on the base substrate by patterning a metal so as to provide a joining force for soldering; and
solder formed on the metal layer of the base substrate through a soldering process so as to mount the sealing unit to the base substrate.

4. The MEMS package as set forth in claim 1, wherein the first joining unit comprises:
an epoxy resin which mounts the sealing unit to the metal layer.

5. The MEMS package as set forth in claim 1, wherein the lid glass is coated on at least one side thereof with an antireflective (AR) coating so as to enhance incident light transmissibility thereof.

6. The MEMS package as set forth in claim 1, wherein the second joining unit comprises:
a metal layer having a predetermined shape formed on the lid glass by patterning a metal so as to provide a joining force for soldering; and
solder formed on the metal layer of the lid glass through a soldering process so as to mount the spacer to the lid glass.

7. The MEMS package as set forth in claim 1, wherein the second joining unit comprises:
an epoxy resin which mounts the spacer to the lid glass.

8. A method of manufacturing a micro-electro-mechanical system (MEMS) package with a spacer for sealing, comprising:
providing an MEMS element on a base substrate;
providing a first joining unit on the base substrate so that the first joining unit surrounds the MEMS element;
preparing a sealing unit which hermetically seals the MEMS element of the base substrate from an external environment; and
mounting the sealing unit to the base substrate using the first joining unit, thus hermetically sealing the MEMS element from the external environment.

9. The method as set forth in claim 8, further comprising:
providing a passivation layer on the base substrate so as to prevent the MEMS element from being short-circuited to the base substrate.

10. The method as set forth in claim 8, wherein the preparing of the sealing unit comprises:
preparing a lid glass which covers the MEMS element;
providing a second joining unit on a predetermined region of the lid glass; and
mounting a spacer, which secures an MEMS moving space where the MEMS element is free to move vertically, to the lid glass using the second joining unit so that the spacer is integrated with the lid glass.
